(19) United States
(12) Patent Application Publication
(10) Pub. No.: US 2012/0032165 A1
(43) Pub. Date: Feb. 9, 2012

(54) AQUEOUS SOLUTION COMPOSITION FOR FLUORINE DOPED METAL OXIDE SEMICONDUCTOR AND THIN FILM TRANSISTOR INCLUDING THE SAME

(75) Inventors: Byeong-Soo BAE, Daejeon (KR); Jun-Hyuck JEON, Daejeon (KR)

(73) Assignee: KOREA ADVANCED INSTITUTE OF SCIENCE AND TECHNOLOGY, Daejeon (KR)

(21) Appl. No.: 13/198,232

(22) Filed: Aug. 4, 2011

(30) Foreign Application Priority Data
Aug. 6, 2010 (KR) 10-2010-0075803
Aug. 1, 2011 (KR) 10-2011-0076685

(51) Int. Cl. H01L 29/786; H01B 1/20; H01B 1/06; H01B 1/12; H01L 29/26; H01L 21/36

(52) U.S. Cl. 257/43; 438/104; 252/500; 252/521.5; 252/520.22; 252/520.1; 252/519.5; 252/520.4; 252/520.5; 252/521.2; 252/519.2; 257/E29.296; 257/E29.079; 257/E21.461

(57) ABSTRACT

Provided are an aqueous solution composition for fluorine doped metal oxide semiconductor, a method for manufacturing a fluorine doped metal oxide semiconductor using the same, and a thin film transistor including the same. The aqueous solution composition for fluorine doped metal oxide semiconductor includes: a fluorine compound precursor made of one or two or more selected from the group consisting of a metal compound containing fluorine and an organic material containing fluorine; and an aqueous solution containing water or catalyst. The method for manufacturing a fluorine doped metal oxide semiconductor, includes: preparing an aqueous solution composition for fluorine doped metal oxide semiconductor, coating a substrate with the aqueous solution composition; and performing heat treatment on the coated substrate to form the fluorine doped metal oxide semiconductor. The thin film transistor of the present invention can exhibit excellent electrical properties even at a temperature for low-temperature annealing, as compared with the metal oxide semiconductor thin film transistor of the related art.

### CROSS-REFERENCE TO RELATED APPLICATIONS

This application claims priority under 35 U.S.C. §119 to Korean Patent Application No. 10-2010-0075803/10-2011-0076685, filed on Aug. 6, 2010/Aug. 1, 2011, in the Korean Intellectual Property Office, the disclosure of which is incorporated herein by reference in its entirety.

### TECHNICAL FIELD

The present invention relates to an aqueous solution composition for fluorine doped metal oxide semiconductor, a method for manufacturing a fluorine doped metal oxide semiconductor, a fluorine doped metal oxide semiconductor prepared by the manufacturing method, and a thin film transistor including the same.

### BACKGROUND

A thin film transistor (TFT) is used in various fields, and particularly used as a switching element or a driving element in a flat panel display device, such as a liquid crystal display (LCD), an organic light emitting diode (OLED) display, electrophoretic display, or the like. The thin film transistor is used in an RFID, a sensor, or the like, and a range of use thereof is widening.

The thin film transistor includes a gate electrode connected to a gate line for transmitting a scan signal therethrough, a source electrode connected to a data line for transmitting a signal to be applied to a pixel electrode, a drain electrode facing the source electrode, and a semiconductor electrically connected to the source and drain electrodes.

Among them, the semiconductor is an important factor, which determines electrical properties of the thin film transistor, and silicon (Si) is the most frequently used as the semiconductor. The silicon is divided into amorphous silicon and polycrystalline silicon according to a crystalline form. The amorphous silicon is simple in a manufacturing process, but has lower charge carrier mobility, and thus, the amorphous silicon has a limit in manufacturing a high-performance thin film transistor. The polycrystalline silicon has high charge carrier mobility but requires a crystallizing step, and thus, high manufacturing costs and complex processes are needed in using the polycrystalline silicon. A metal oxide semiconductor can be used as an alternative to these amorphous silicon and polycrystalline silicon. The metal oxide semiconductor does not need separate processes for crystallizing a semiconductor, and can increase charge carrier mobility by addition and substitution of metal oxide components. InGaO₃(ZnO)₅, which is a semiconductor presented by the Hosono Group (Science, vol. 300, p. 1269, 2003: Non-patent document 1), has the best switching characteristic, including charge carrier mobility, in the metal oxide semiconductors currently known. Besides, Wager, et al., used a ZnO thin film as a semiconductor (Appl. Phys. Lett, vol. 82, p. 733, 2003: Non-patent document 2), and M. Kawasaki, et al., of Japan disclosed a technique on a transparent transistor including a semiconductor of ZnO, MgZnO, CdZnO, or the like and having an inorganic double insulation film structure in U.S. Pat. No. 6,563,174 B2 (Patent document 1).

A vacuum deposition method or a solution process may be used to manufacture a metal oxide semiconductor. As for the vacuum deposition method, a laser molecular beam epitaxy technique, a pulsed laser deposition technique, a physical and chemical vapor deposition technique, an RF and DC sputtering technique, an ion beam sputtering technique, or the like may be used, or heat treatment at high temperature may be performed after deposition. Meanwhile, as for the solution process, spin coating, dip coating, bar coating, screen printing, slide coating, roll coating, slit coating, spray coating, dipping, dip-pen, inkjet printing, nano-dispensing, or inkjet printing is performed on a Si substrate by using a solution composition. The solution process can provide excellent physical properties as compared with the vacuum deposition method and achieve a large area, thereby manufacturing the transistor at low costs. Meanwhile, the amount of precursor is simply regulated to facilitate the change in a component ratio of a thin film.

Chang from Oregon University, USA, manufactured an InZnO thin film or an InZnSnO thin film by employing a solution process using a metal halide precursor, according to US2007/0184576A1 (Patent document 2). Metal chloride, among metal halide precursors, was mainly used, and, in a case of a solution composition including chlorine, high-temperature heat treatment (500° C. or higher) is needed due to high thermal decomposition temperature, and electrical properties such as an on-to-off ratio, a threshold voltage, a sub-threshold swing, and the like, are not good while charge carrier mobility is excellent. After that, studies on manufacturing of a solution-processed oxide thin film transistor using a metal organic material, such as metal acetate or metal acetylacetonate, which has a low thermal decomposition temperature. S. J. Seo, et al., manufactured a ZnSnO thin film having excellent electrical properties, such as change mobility, current ratio, threshold voltage, sub-threshold swing, and the like, by using zinc acetate and tin chloride (J. Phys. D: Appl. Phys. 42 035106, 2009: Non-patent document 3).

However, in the case of a solution process using the organic solvent as above, a high-temperature heat treatment of 400 to 500° C. is basically required in order to remove an organic material present in a solvent, a precursor, an additive stabilizer, and a surfactant, or an inorganic material generated by the reaction thereof. In addition, additive vacuum heat treatment and humid heat treatment need to be performed to remove organic residues within a semiconductor thin film. Therefore, a manufacturing process for performance is complicated and the manufacturing cost is high, considering the performance of the semiconductor.

### CITED REFERENCES

### Cited Patent Documents

(Patent document 1) U.S. Pat. No. 6,563,174 B2

(Patent document 2) US 2007/0184576 A1

### Cited Non-Patent Documents

(Non-patent document 1) Science, vol. 300, p. 1269, 2003

(Non-patent document 2) Appl. Phys. Lett, vol. 82, p. 733, 2003

(Non-patent document 3) J. Phys. D: Appl. Phys. 42 035106, 2009

### SUMMARY

As described above, a thin film transistor, which includes a semiconductor layer having high mobility and excellent current ratio, threshold voltage characteristics, and element reliability, even at a low manufacture temperature below 400° C., needs to be developed.

An aqueous solution composition for fluorine doped metal oxide semiconductor according to the present invention leaves less organic residues than a solution composition using an organic solvent, and a thin film transistor including the semiconductor manufactured according to the present invention has excellent performance, considering the manufacturing temperature. Therefore, the present invention can significantly lower a temperature for heat treatment of manufacturing the fluorine doped metal oxide semiconductor.

An embodiment of the present invention is to provide an aqueous solution composition for fluorine doped metal oxide semiconductor including fluorine, capable of having excellent electrical properties and having and a manufacturing advantage of low-temperature annealing, based on a low resistance value obtained by adding fluorine in the components of the existing oxide. Another object of the present invention is to provide a method for manufacturing a fluorine doped metal oxide semiconductor using the composition and a thin film transistor including the same.

In one general aspect, an aqueous solution composition for fluorine doped metal oxide semiconductor, includes: a fluorine compound precursor made of one or two or more selected from the group consisting of a metal compound containing fluorine and an organic material containing fluorine; and an aqueous solution containing water or catalyst.

The present invention provides an aqueous solution composition for fluorine doped metal oxide semiconductor prepared by involving a fluorine compound precursor in forming a complex, or a hydrolysis or condensation reaction within a synthesis solvent, the fluorine compound precursor being one or more selected from the group consisting of a metal compound containing fluorine and an organic material containing fluorine. In addition, the present invention provides a fluorine doped metal oxide semiconductor thin film transistor including the same.

A metal of the metal compound containing fluorine may be selected from the group consisting of Li, Na, Rb, Sc, Be, Mg, Ca, Sr, Ba, Ti, Zr, Hf, V, Nb, Ta, Cr, Mo, W, Mn, Te, Re, Fe, Ru, Os, Co, Rh, Ir, Ni, Pd, Pt, Cu, Ag, Au, Zn, Cd, Hg, B, Al, Ga, In, Tl, Si, Ge, Sn, Pb, P, As, Sb, and Bi.

Examples of the metal compound containing fluorine may include MFₓ type metal fluoride made by bonding of metal (M) and fluorine (F), and MFₓ.yH₂O type metal fluoride hydrate, which is complexed with water. Here, x represents a natural number of 1 or greater according to the valency of M, and y represents degree of hydration.

Specific examples thereof may include AlF₃, AgF, BaF₂, BiF₃, BiF₅, CdF₂, CaF₂, CeF₃, CeF₅, CsF₂, CrF₃, CoF₂, CoF₃, CuF₂, DyF₃, ErF₃, EuF₂, GaF₃, GdF₃, GeF₂, GeF₄, HfF₄, HoF₃, InF₃, FeF₃, LaF₃, PbF₂, LiF, MgF₂, MnF₂, MnF₃, Hg₂F₂, HgF₂, HgF₄, NaF, NbF₄, NdF₃, NiF₂, MoF₆, KF, RbF, SbF₃, SbF₅, ScF₃, SiF₄, SnF₂, SnF₄, SrF₂, TaF₅, TiF₃, TiF₄, TlF, TmF₃, VF₃, WF₅, YF₃, YbF₃, ZnF₂, ZrF₄, AlF₃.xH₂O, AlF₃.3H₂O, CrF₃.4H₂O, CoF₂.4H₂O, CuF₂.zH₂O, FeF₃.3H₂O, FeF₂.4H₂O, InF₃.3H₂O, KF.2H₂O, GaF₃.3H₂O, ZnF₂.zH₂O, or ZrF₄.zH₂O. In addition, examples of the metal compound containing fluorine may include an MF_{X}S_{Y} type metal fluoro-salt or an MF_{X}(OR)S_{Y} type metal fluoro-alkoxide, which includes metal (M), fluorine (F), salt (S), and alkyl group (R), or a metal complex, such as [MF_{X}(OR)S_{Y}]ₙ type metal fluoro oxo-oligomer or -polymer, which is made by reaction thereof. Here, X, Y, z and n independently represent a natural number of 1 or greater, and z represents a degree of hydration. Specific examples thereof may include SnF₂(acac)₂, SnF(OC₂H₅)(acac)₂, SnF(OCH(CH₃)₂)(acac)₂, SnF(OC(CH₃)₂C₂H₅)(acac)₂, (CF₃COCHCOCH₃)₂—Sn, C₃₃H₇₀F₂Sn₂, [(CH₃)₂CHCH₂]₂AlF, or [(CH₃CH₂CH₂CH₂)₃SnF]ₙ. The metal compound containing fluorine may be one or more selected from the group consisting of the above materials.

The organic materials containing fluorine may be one or more selected from the group consisting of HF, NH₄F, NH₄F.HF, NH₄HF₂, C₆H₅F, C₂H₂F₂, C₃F₃N₃, CF₃COOH, CF₃CF₂CF₂CO₂H, CF₃CH₂OH, CHF₂CHF₂, CHF₂CF₃, CHF₂CH₃, CF₃CH₂CF, CH₃CF₃, CBr₂F₂, CHF₂CH₂F, CF₃CH₂CF₃, CF₃CFCF₂, CF₃CH₂F, (CH₃)₄NF, CH₃ (CH₂)₆F, CH₃ (CH₂)₇F, CH₃ (CH₂)₄F, (CH₃)₃SiF, (O₂N)₂C₆H₃F, CF₃C₆H₄NH₂, C₆H₄FNO, (C₂H₅)₃N.3HF, C₈H₉FN₂O₂S.HCl, C₇H₈FNO₃S, CH₃COF, C₆H₅SO₂F, C₆H₅COF, C₅H₅N.(HF)ₓ, CH₃C₆H₄SO₂F, CF₃(CF₂)₃SO₂F, CF₃ (CF₂)₇SO₂F, C₇H₇FO₂S, C₆H₅CH₂N(CH₃)₃F.zH₂O, [CH₃ (CH₂)₃]₄NF, [CH₃ (CH₂)₃]₄NF.zH₂O, [CH₃ (CH₂)₃]₄NF.3H₂O, (CH₃)₄N(F).4H₂O, (C₂H₅)₄N(F).2H₂O, (C₂H₅) 4NF.zH₂O, H₂C₆H₃ (Cl)SO₂F, ICF₂CF₂OCF₂CF₂SO₂F, and [2,4,6-(CH₃)₃C₆H₂]₂BF.

The aqueous solution composition for fluorine doped metal oxide semiconductor according to the present invention may further include a metal salt. Anion of the metal salt may be selected from the group consisting of hydroxide, nitrate, acetate, propionate, acetylacetonate, 2,2,6,6-tetramethyl-3,5-heptandionate, methoxide, secondary-butoxide, tertiary butoxide, n-propoxide, i-propoxide, ethoxide, phosphate, alkyl phosphate, perchlorate, sulfate, iodide, alkyl sulfonate, phenoxide, bromide, and chloride.

As the solvent, water may be used or water including a catalyst may be used. The catalyst may be a mixture of one or more selected from the group consisting of urea, acid, and base compounds.

In the aqueous solution composition for fluorine doped metal oxide semiconductor according to the present invention, the fluorine doped metal oxide precursors is formed into a fluorine doped metal oxide monomer by hydrolysis and/or condensation within the synthesis solvent even at room temperature. When the kinds of metal ions of the formed fluorine doped metal oxide monomers are different, a nucleophilic reaction is possible due to different values of electronegativity, and the condensation of different kinds of fluorine doped metal oxide monomers induces fluorine doped metal oxide oligomers. This aqueous solution composition for fluorine doped metal oxide semiconductor containing fluorine doped metal oxide monomers and oligomers contains many M-O-M bonds, and thus, low-temperature annealing is possible in view of manufacturing the fluorine doped metal oxide semiconductor. Moreover, a fluorine doped metal oxide semiconductor manufactured by using the aqueous solution composition and employing low-temperature annealing can have excellent charge carrier mobility, on/off current ratio, and sub-threshold swing.

The aqueous solution composition for fluorine doped metal oxide semiconductor according to the present invention allows a complex to be formed within the synthesis solution, apart from the hydrolysis and condensation. A complex may be formed, and the complex has a structure, in which ligands, such as water (H₂O), a hydroxyl group (OH—), an amine group (NH₃—), a carbonyl group (CH₃—), a halogen group (F—, Cl—), and a cyano group (CN—), are coordinated to a metal ion. This complex structure makes a uniform distribution of metal ions in the synthesis solution, and thus, a homogeneous solution can be prepared, thereby improving quality and uniformity of the thin film coated on a substrate. Therefore, it is possible to manufacture a fluorine doped metal oxide semiconductor, by which a thin film having uniform charge carrier mobility, on/off current ratio, and sub-threshold swing can be formed.

Hereinafter, a method for manufacturing a fluorine-containing metal oxide semiconductor according to the present invention will be described.

The present invention provides a method for a fluorine doped metal oxide semiconductor, including coating a substrate with an aqueous solution composition for fluorine doped metal oxide semiconductor, and performing heat treatment on the coated substrate to form a fluorine doped metal oxide semiconductor.

Examples of the coating method may include spin coating, dip coating, bar coating, screen printing, slide coating, roll coating, slit coating, spray coating, dipping, dip-pen, nano-dispensing, inkjet printing, and the like.

In the method for manufacturing the fluorine doped metal oxide semiconductor, the temperature for heat treatment is particularly not limited, but is preferably 100 to 500° C., and more preferably, 100 to 350° C.

Furthermore, the present invention provides a fluorine doped metal oxide semiconductor prepared by the method for manufacturing the fluorine doped metal oxide semiconductor.

The present invention is directed to a thin film transistor, including a gate substrate, a fluorine doped metal oxide semiconductor overlapping the gate substrate, a source electrode electrically connected to the fluorine doped metal oxide semiconductor, and a drain electrode electrically connected to the fluorine doped metal oxide semiconductor and facing the source electrode.

### BRIEF DESCRIPTION OF THE DRAWINGS

FIG. 1 is a schematic diagram showing a procedure for synthesizing an aqueous solution composition for fluorine doped metal oxide semiconductor and a method for manufacturing a for fluorine doped metal oxide semiconductor thin film, according to the present invention;

FIG. 2 is a cross-sectional view showing a thin film transistor of the present invention;

FIGS. 3 and 4 are cross-sectional views showing a method for manufacturing the thin film transistor of FIG. 2;

FIG. 5 is a plan view of a thin film transistor of the present invention;

FIG. 6 is a cross-sectional view of the thin film transistor of FIG. 5, taken along the line V-V′;

FIG. 7 is a graph showing a thermogravimetric analysis result of a fluorine doped zinc tin oxide semiconductor composition according to Example 1 of the present invention, and inserted figures in FIG. 7 are graphs showing thermogravimetric analysis results of a fluorine doped zinc oxide semiconductor composition and a fluorine doped tin oxide semiconductor composition;

FIG. 8 is a graph showing current-voltage characteristics of a thin film transistor including a fluorine doped zinc tin oxide semiconductor according to Example 1 of the present invention;

FIG. 9 is a graph showing a transfer curve of the thin film transistor including the fluorine doped zinc tin oxide semiconductor according to Example 1 of the present invention, and an inserted figure in FIG. 9 is a graph showing an X-ray photoelectron spectroscopy (XPS) analysis result exhibiting the presence of fluorine 1s peak (F 1s) in a fluorine doped zinc tin oxide semiconductor layer according to Example 1 of the present invention;

FIG. 10 is a graph showing a thermogravimetric analysis result of a fluorine doped indium zinc oxide semiconductor composition according to Example 6 of the present invention;

FIG. 11 is a graph showing current-voltage characteristics of a thin film transistor including a fluorine doped indium zinc oxide semiconductor according to Example 6 of the present invention;

FIG. 12 is a graph showing a transfer curve of the thin film transistor including the fluorine doped indium zinc oxide semiconductor according to Example 6 of the present invention, and an inserted figure in FIG. 12 is a graph showing an XPS analysis result exhibiting the presence of fluorine 1s peak (F 1s) in a fluorine doped indium zinc oxide semiconductor layer according to Example 6 of the present invention;

FIG. 13 is a graph showing a thermogravimetric analysis result of an aqueous solution composition for zinc tin oxide semiconductor according to Comparative Example 1 of the present invention;

FIG. 14 is a graph showing a transfer curve of a thin film transistor including a zinc tin oxide semiconductor according to Comparative Example 1 of the present invention; and

FIG. 15 is a graph showing a transfer curve of a thin film transistor including a zinc tin oxide semiconductor according to Comparative Example 2 of the present invention.

### DETAILED DESCRIPTION OF MAIN ELEMENTS

10: GATE SUBSTRATE
20: GATE ELECTRODE 25: GATE LINE
30: GATE INSULATING FILM
40: SOURCE ELECTRODE 45: DRAIN ELECTRODE
50: FLUORINE DOPED METAL OXIDE SEMICONDUCTOR LAYER 55: FLUORINE DOPED METAL OXIDE SEMICONDUCTOR
C: CHANNEL OF THIN FILM TRANSISTOR

### DETAILED DESCRIPTION OF EMBODIMENTS

Advantages and features of the present invention and methods to achieve them will be elucidated from exemplary embodiments described below in detail with reference to the accompanying drawings.

However, the present invention is not limited to the exemplary embodiments disclosed herein but will be implemented in various forms. The exemplary embodiments are provided by way of example only so that a person of ordinary skill in the art can fully understand the disclosures of the present invention and the scope of the present invention. Therefore, the present invention will be defined only by the scope of the appended claims.

An element or layer is referred to as being “on” or “above” another element or layer, which includes a case where it can be directly on another element or layer as well as a case where intervening elements or layers may be present. Whereas, when an element is referred to as being “directly on” or “directly above” another element or layer, there are no intervening elements or layers present. The term, “and/or” means to include all combinations of each and on ore more of the items to be stated. Spatially relative terms, “below,” “beneath,” “lower,” “above,” “upper,” and the like, may be used herein for ease of description to describe one element or the feature's relationship to another element(s) or feature(s) as illustrated in the figures. The spatially relative terms are intended to include different directions of the element in use or operation in addition to the direction depicted in the figures. Like reference numerals refers to like components throughout the specification.

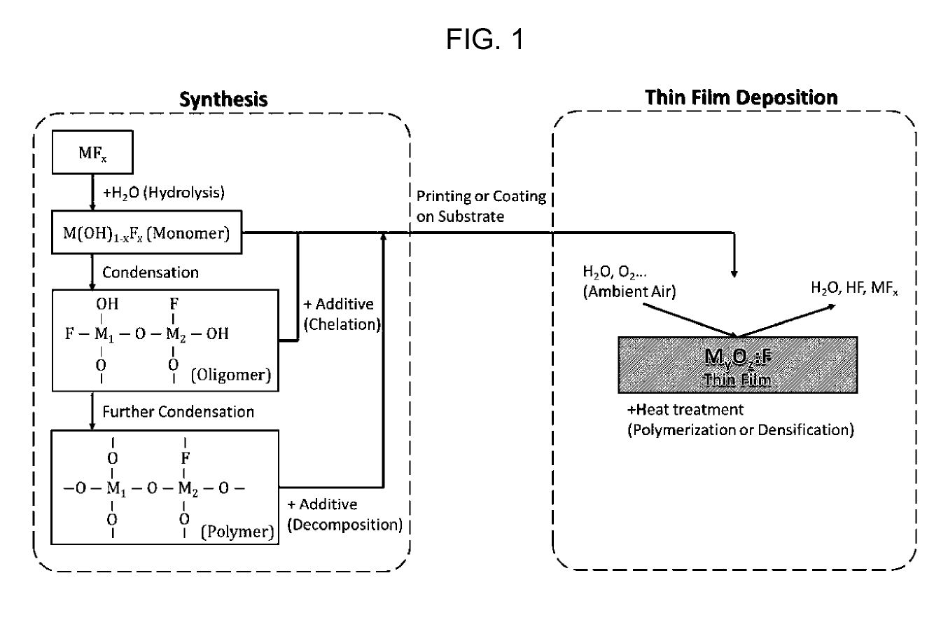

FIG. 1 is a schematic diagram showing a procedure for synthesizing an aqueous solution composition for fluorine doped metal oxide semiconductor and a method for manufacturing a fluorine doped metal oxide semiconductor thin film, according to the exemplary embodiment of the present invention. Metal hydroxide (HO-M-OH) or metal hydroxy-fluoride (F-M-OH) monomers are formed by a hydrolysis reaction of metal fluoride with water, which is a fluorine doped metal compound used in the present invention. The monomers are formed into oligomers by a condensation reaction, and then formed into chelate complexes or decomposed into smaller-sized molecules by addition of catalysts or the like. The aqueous solution composition for fluorine doped metal oxide semiconductor thus synthesized is coated by a printing or coating method, and subjected to heat treatment, thereby finally manufacturing a fluorine doped metal oxide semiconductor thin film doped with fluorine.

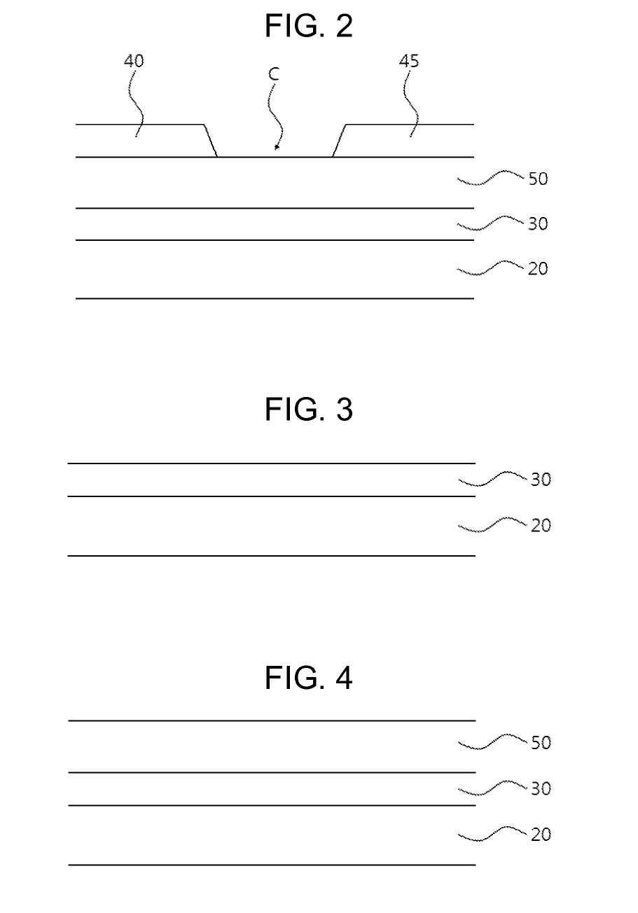

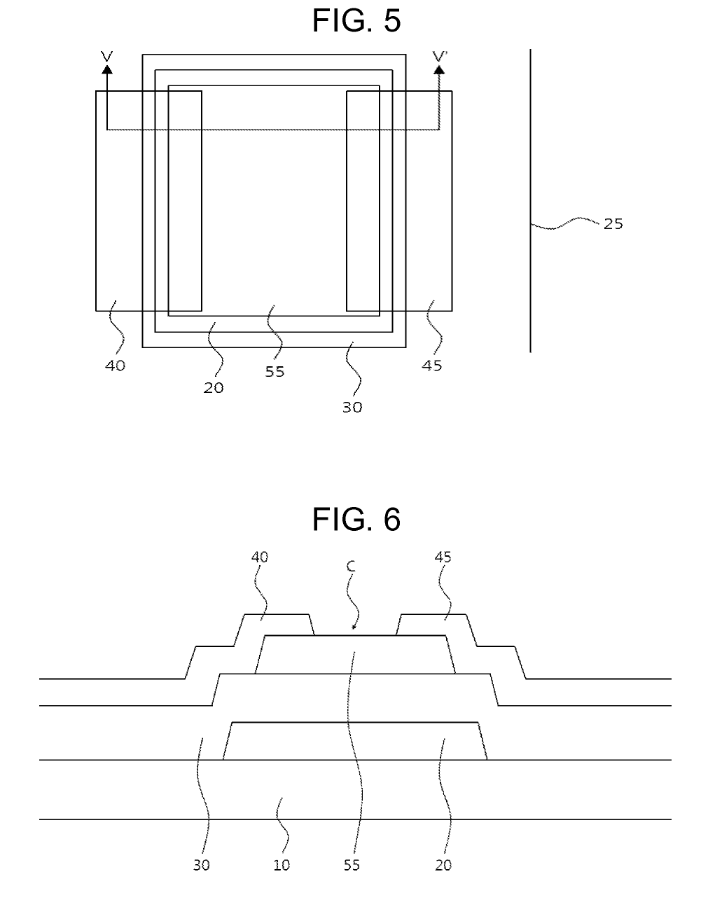

FIG. 2 is a cross-sectional view showing a thin film transistor of the present invention. FIGS. 3 and 4 are cross-sectional views sequentially showing a method for manufacturing the thin film transistor of FIG. 2.

Referring to FIG. 2, a thin film transistor of the present invention in which a gate insulating layer (30) is formed on a gate substrate (20) to cover the entire surface of the gate substrate (20).

Referring to FIG. 3, an upper portion of the gate substrate (20), which is made of silicon highly doped with p-type or n-type impurities, is oxidized at a high temperature, to form a gate insulating film (30) made of silicon oxide (SiOₓ). Differently from this, the gate insulating film (30) may be formed by stacking silicon oxide (SiOₓ), silicon nitride (SiNₓ), an organic insulating material, aluminum oxide (AlₓO_{y}), hafnium oxide(HfOₓ), or a mixture or compound of two or more therefrom. The gate substrate (20) is highly doped with p-type or n-type impurities, thereby retaining a conductive property, and may contain silicon (Si).

Then, referring to FIG. 4, a fluorine doped metal oxide semiconductor layer (50) including fluorine is formed on the gate insulating film (30) by using the aqueous solution composition for fluorine doped metal oxide semiconductor according to the present invention. The fluorine doped metal oxide semiconductor layer (50) may be formed by coating the aqueous solution composition for fluorine doped metal oxide semiconductor on the gate insulating film (30) and then performing heat treatment on the resulting substrate.

The present invention is directed to an aqueous solution composition for fluorine doped metal oxide semiconductor, including a fluorine compound of one or more selected from a metal compound containing fluorine and an organic material containing fluorine; and an aqueous solution including water or catalyst.

Examples of the fluorine doped metal compound containing fluorine may include metal fluoride and a metal fluoro-complex. Examples of metal of the metal compound containing fluorine may include at least one selected from lithium (Li), sodium (Na), potassium (K), rubidium (Rb), cesium (Sc), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Te), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), boron (B), aluminum (Al), gallium (Ga), Indium (In), thallium (Tl), silicon (Si), germanium (Ge), tin (Sn), lead (Pb), phosphorus (P), arsenic (As), antimony (Sb), and bismuth (Bi).

Preferable examples of the fluorine doped metal compound may include metal fluoride, such as MgF₂, AlF₃, GaF₃, InF₃, ZnF₂, SnF₂, SnF₄, TiF₃, TiF₄, or the like, and metal fluoride hydrate, such as AlF₃.xH₂O, AlF₃.3H₂O, GaF₃.3H₂O, InF₃.3H₂O, ZnF₂.xH₂O, or the like. In addition, a metal fluoro salt, such as SnF₂ (acac)₂, SnF (OC₂H₅)(acac)₂, SnF(OCH(CH₃)₂)(acac)₂, SnF(OC(CH₃)₂C₂H₅)(acac)₂, (CF₃COCHCOCH₃)₂—Sn, or the like, or metal fluoro-alkoxide, or a metal fluoro complex, such as a metal fluoro oxo-oligomer and a metal fluoro oxo-polymer made by reaction thereof, may be used.

The organic material containing fluorine may be selected from CHF₃, CH₃F, C₂H₅F, C₂HF₅, CH₂F₂, CBrF₃, ClF₃, SF₆, CF₄, C₂F₄, C₂F₆, C₃F₆, C₃F₈, C₄F₈, SiF₄, NF₃, HF, NH₄F, NH₄HF₂, CF₃COOH, CF₃CF₂CF₂CO₂H, CF₃CH₂OH, CHF₂CHF₂, CHF₂CF₃, CHF₂CH₃, CF₃CH₂CF, CH₃CF₃, CHF₂CH₂F, CF₃CH₂CF₃, CF₃CFCF₂, CF₃CH₂F, fluorinated propane, fluorinated propylene, fluorinated ethylene, or a mixture thereof, but limited thereto.

The aqueous solution composition for fluorine doped metal oxide semiconductor may include a metal salt, and an anion of the metal salt may include at least one selected from hydroxide, nitrate, acetate, propionate, acetylacetonate, 2,2,6,6-tetramethyl-3,5-heptanedionate, methoxide, sec-butoxide, 3-butoxide, n-propoxide, i-propoxide, ethoxide, phosphate, alkyl phosphate, perchlorate, sulfate, alkyl sulfonate, penoxide, bromide, iodide, and chloride, but is not limited thereto.

The metal compound containing fluorine and the metal salt may form a complex together with the synthesis solvent.

The synthesis solvent may be an aqueous solution including water or catalysts.

More preferably, one or two or more, which are selected from distilled water, ion exchange water, deionized water, an aqueous hydrochloride(HCl) solution, an aqueous sulfuric acid (H₂SO₄) solution, an aqueous nitric acid (HNO₃) solution, an aqueous fluoric acid (HF) solution, an aqueous boric acid (H₃BO₃) solution, an aqueous phosphoric acid (H₃PO₄) solution, an aqueous carbonic acid (H₂CO₃) solution, an aqueous peroxide (H₂O₂) solution, an aqueous acetic acid (CH₃COOH) solution, ammonia water, and an aqueous urea solution, may be included.

The catalyst may be contained in a content of 0.01 to 45 wt % based on a weight of the aqueous solution composition of a fluorine doped metal oxide semiconductor.

If the catalyst is contained in a content of the range, the interaction between the precursor and the synthesis solvent may be promoted or alleviated, thereby improving solubility of the fluorine compound and thin film coating property of the aqueous solution composition for fluorine doped metal oxide semiconductor.

The present invention is directed to a method for manufacturing a fluorine doped metal oxide semiconductor, including coating a substrate with the aqueous solution composition for fluorine doped metal oxide semiconductor, and performing heat treatment on the coated substrate to form a fluorine doped metal oxide semiconductor.

The coating process may be performed by using at least one of spin coating, dip coating, bar coating, screen printing, slide coating, roll coating, slit coating, spray coating, dipping, dip-pen, nano-dispensing, and inkjet printing.

More specifically, the present invention provides a method for manufacturing a fluorine doped metal oxide semiconductor, including:

preparing an aqueous solution composition for fluorine doped metal oxide semiconductor, including a fluorine compound of one or more selected from a metal compound containing fluorine and an organic material containing fluorine; an aqueous solution including water or catalyst; and,

coating a substrate with the aqueous solution composition for fluorine doped metal oxide semiconductor, and performing heat treatment on the coated substrate to form a fluorine doped metal oxide semiconductor.

In the manufacturing method, the aqueous solution composition for fluorine doped metal oxide semiconductor may be subjected to a stirring step. Here, the stirring step may be performed at room temperature or at a temperature of about 100° C. or lower, for 1 to 100 hours, by using a stirring machine or ultrasonic treatment. As such, the stirring step is performed to improve solubility and thin film coating property and improve electrical, mechanical, and thermal properties of the thin film. In addition, a single coating method or multiple coating methods may be used in order to obtain a thin film with a desired thickness.

The aqueous solution composition for fluorine doped metal oxide semiconductor coated on the substrate is subjected to heat treatment, thereby growing fluorine doped metal oxide containing fluorine. Here, the atmosphere containing vacuum, nitrogen, oxygen, hydrogen, or large amount of vapor, or one gas type of the fluorine organic compounds may be used for a heat treatment atmosphere. The heat treatment may be performed at a relatively low temperature, that is, at a temperature of no less than about 100° C. and no more than 500° C.

In particular, according to the present invention, the fluorine doped metal oxide can be sufficiently annealed even at a low temperature of 100 to 350° C.

As for the fluorine doped metal oxide semiconductor according to the present invention, a metal (X), as a component of the finally grown fluorine doped metal oxide (FXO), may have a single component type or a multiple of lithium (Li), sodium (Na), potassium (K), rubidium (Rb), cesium (Sc), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Te), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), boron (B), aluminum (Al), gallium (Ga), Indium (In), thallium (Tl), silicon (Si), germanium (Ge), tin (Sn), lead (Pb), phosphorus (P), arsenic (As), antimony (Sb), bismuth (Bi), or the like. In addition, the fluorine doped metal oxide semiconductor may be crystalline or amorphous.

A thin film transistor according to the present invention will be described with reference to FIGS. 5 and 6. The same reference numeral is provided to the same constitutional component as the afore-described exemplary embodiment, and the same description will be omitted.

Referring to FIG. 6, in a thin film transistor according to the present invention, a gate line (25) including a gate electrode (20) is formed on an insulating substrate (10). The gate line (25) may be made of one of silicon (Si) highly doped with p-type or n-type impurities, metals of aluminum, silver, copper, molybdenum, chrome (Cr), tantalum (Ta), and titanium (Ti), and oxides of indium tin oxide (Sn:In₂O₃), fluorine doped tin oxide (F:SnO₂), antimony tin oxide (Sb:SnO₂), indium zinc oxide (Zn:In₂O₃), and aluminum zinc oxide (Al:ZnO). The gate line (25) may have a multiple layer structure, in which two different conductive films are included, but is not limited thereto. A gate conductive layer is stacked and patterned to form the gate line (25) including the gate electrode (20).

Then, in a case where the gate line (25) is made of silicon, the gate line (25) is oxidized at a high temperature to form a gate insulating film (30) made of silicon oxide (SiOx). In another case, silicon oxide (SiOx), silicon nitride (SiNx), aluminum oxide (AlOx), hafnium oxide (HfOx), or an organic insulating material is stacked to form the gate insulating film (30).

Then, a metal oxide semiconductor (55) is formed by forming and patterning a fluorine doped metal oxide semiconductor layer made of fluorine doped metal oxide containing fluorine on the gate insulating film (30) using the aqueous solution composition and the method for manufacturing the fluorine doped metal oxide semiconductor according to the present invention.

Then, a conductive layer is stacked on the fluorine doped metal oxide semiconductor (55) by evaporation or sputtering, and then is patterned, to form a source electrode (40) and a drain electrode (45).

### Example 1

The fluorine doped metal oxide semiconductor layer (50) according to Example 1 of the present invention is made of an oxide including fluorine (F), zinc (Zn), and tin (Zn). In order to manufacture a thin film transistor represented by the present invention, an aqueous solution composition for fluorine doped metal oxide semiconductor was prepared as follows.

0.001 mol of tin fluoride (SnF₂) and 0.001 mol of zinc fluoride hydrate (ZnF₂.xH₂O) were added into 10 ml of deionized water, and then the resultant mixture was stirred at room temperature for 1 hour in order to create a smooth reaction, thereby preparing an aqueous solution composition for fluorine doped metal oxide semiconductor.

The prepared aqueous solution composition for fluorine doped metal oxide semiconductor was applied to a device having a structure represented below.

A substrate S was made of silicon highly doped with p-type impurities, and had conductivity. SiO₂ was grown on the substrate S by 100 nm, thereby forming a gate insulating film on the substrate S. The prepared aqueous solution composition for fluorine doped metal oxide semiconductor was coated on the substrate S by a spin coating method, and the resultant substrate was subjected to heat treatment at 250° C. for 12 hours, thereby forming a fluorine doped metal oxide semiconductor layer. A source electrode and a drain electrode facing each other were formed on the fluorine doped metal oxide semiconductor layer through deposition of aluminum using E-beam evaporation.

That is, a thin film transistor was manufactured, including a gate substrate, a fluorine doped metal oxide semiconductor overlapping the gate substrate, a source electrode electrically connected to the fluorine doped metal oxide semiconductor, and a drain electrode electrically connected to the fluorine doped metal oxide semiconductor and facing the source electrode (FIG. 2). Here, a channel C of the thin film transistor was defined in the fluorine doped metal oxide semiconductor layer (50) between the source electrode 40 and the drain electrode (45).

In order to evaluate electrical properties of the manufactured thin film transistor, charge carrier mobility, on-off current ratio, sub-threshold swing, and threshold voltage thereof were measured, and the measurement results were tabulated in Table 1.

### Example 2

A solution composition for fluorine doped metal oxide semiconductor of Example 1 was coated on the substrate S by a spin coating method, and the resultant substrate was subjected to heat treatment at 350° C. for 1 hour. Then, like Example 1, aluminum source and drain electrodes were stacked, thereby manufacturing a thin film transistor, and electrical properties of the thin film transistor were tabulated in Table 1.

### Example 3

In a thin film transistor including a fluorine doped zinc tin semiconductor layer according to Example 3 of the present invention, an aqueous solution composition for fluorine doped metal oxide semiconductor for manufacturing the thin film transistor was prepared, differently from Example 1 previously described, as follows. 0.001 mol of tin fluoride (SnF₂) and 0.001 mol of zinc nitrate hexahydrate (Zn(NO₃)₂.6H₂O) were added into 10 ml of deionized water, and then the resultant mixture was stirred at room temperature for 1 hour in order to create a smooth reaction, thereby preparing an aqueous solution composition for fluorine doped metal oxide semiconductor in which a fluorine doped metal oxide precursor is formed into a fluorine doped metal oxide monomer and a fluorine doped metal oxide oligomer by hydrolysis and condensation within a synthesis solvent. The rest of the procedure was the same as Example 2, and electrical properties of the thin film transistor were tabulated in Table 1.

### Example 4

In a thin film transistor including a fluorine doped zinc tin semiconductor layer according to Example 4 of the present invention, an aqueous solution composition for fluorine doped metal oxide semiconductor for manufacturing the thin film transistor was prepared, differently from Example 3 previously described, as follows. 0.001 mol of tin fluoride (SnF₂) and 0.001 mol of zinc nitrate hexahydrate (Zn(NO₃)₂.6H₂O) were added into 10 ml of deionized water, followed by addition of 0.0005 mol of ammonium fluoride (NH₄F), and then the resultant mixture was stirred at room temperature for 1 hour in order to create a smooth reaction. The rest procedure was the same as Example 2, and electrical properties of the thin film transistor were tabulated in Table 1.

### Example 5

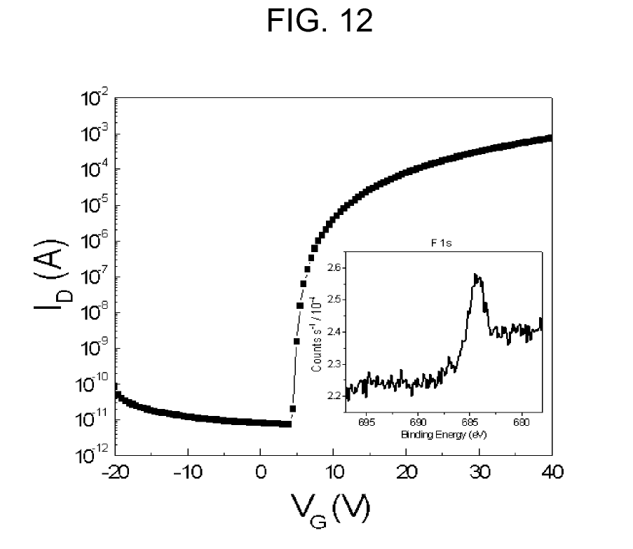

In a thin film transistor including a fluorine doped indium zinc semiconductor layer according to Example 5 of the present invention, an aqueous solution composition for fluorine doped metal oxide semiconductor for manufacturing the thin film transistor was prepared, differently from the examples previously described, as follows. 0.001 mol of indium fluoride trihydrate (InF₂.3H₂O) and 0.0005 mol of zinc fluoride hydrate (ZnF₂.xH₂O) were added into 10 ml of deionized water, and then the resultant mixture was stirred at room temperature for 1 hour in order to create a smooth reaction. The prepared aqueous solution composition for fluorine doped metal oxide semiconductor was coated on the substrate S by a spin coating method, and the resultant substrate was subjected to heat treatment at 250° C. for 1 hour, thereby forming a fluorine doped metal oxide semiconductor layer. A source electrode and a drain electrode facing each other were formed on the fluorine doped metal oxide semiconductor layer through deposition of aluminum using E-beam evaporation. The rest of the procedure was the same as Example 1, and electrical properties of the thin film transistor were shown in FIGS. 11 and 12, and Table 1.

### Example 6

As for a thin film transistor including the fluorine doped indium zinc semiconductor layer according to Example 6 of the present invention, the fluorine doped metal oxide semiconductor layer of Example 5 was coated on the substrate S by a spin coating method, and the resultant substrate was subjected to heat treatment at 350° C. for 1 hour. Then, like Example 1, aluminum source and drain electrodes were stacked, thereby manufacturing a thin film transistor, and electrical properties of the thin film transistor were tabulated in Table 1.

### Example 7

In a thin film transistor including a fluorine doped aluminum indium semiconductor layer according to Example 7 of the present invention, an aqueous solution composition for fluorine doped metal oxide semiconductor for manufacturing the thin film transistor was prepared, differently from Examples previously described, as follows. 0.001 mol of indium fluoride trihydrate (InF₂.3H₂O) and 0.0004 mol of aluminum nitrite nanohydrate (Al(NO₂)₂.9H₂O) were added into 10 ml of deionized water, and then the resultant mixture was stirred at room temperature for 1 hour in order to create a smooth reaction. The rest of the procedure was the same as Example 2, and electrical properties of the thin film transistor were tabulated in Table 1.

### Example 8

In a thin film transistor including a fluorine doped gallium indium semiconductor layer according to Example 8 of the present invention, an aqueous solution composition for fluorine doped metal oxide semiconductor for manufacturing the thin film transistor was prepared, differently from the examples previously described, as follows. 0.001 mol of indium fluoride trihydrate (InF₂.3H₂O) and 0.0004 mol of gallium nitrite trihydrate (Ga(NO₃)₃.3H₂O) were added into 10 ml of deionized water, and then the resultant mixture was stirred at room temperature for 1 hour in order to create a smooth reaction. The rest of the procedure was the same as Example 2, and electrical properties of the thin film transistor were tabulated in Table 1.

### Comparative Example 1

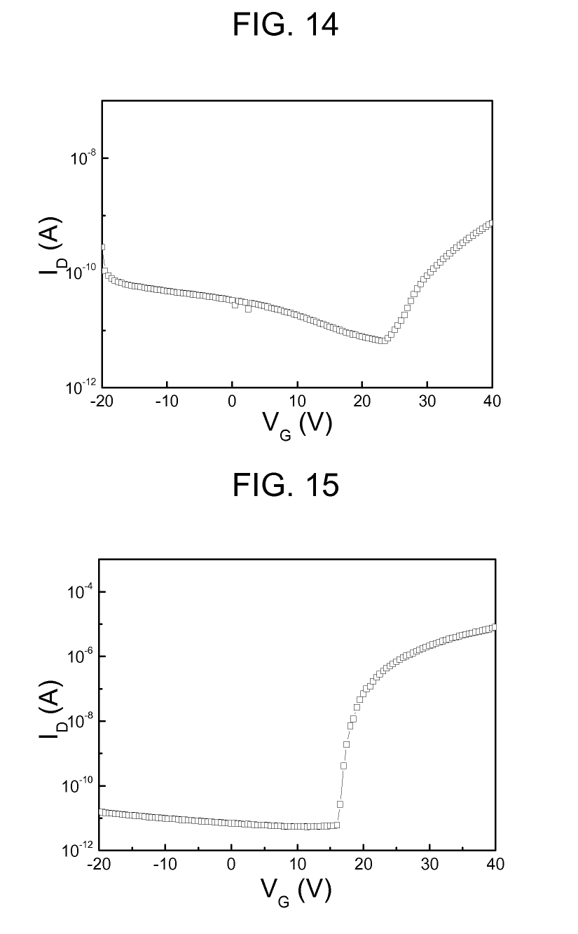

For comparison with Example 1 of the present invention, a solution composition for zinc tin oxide semiconductor prepared based on an organic solvent was used to perform the experiment. 0.001 mol of zinc acetate (Zn(Ac)₂) and 0.001 mol of tin chloride (SnCl₂) were added into 10 ml of 2-methoxy ethanol, which is an organic solvent, followed by addition of 0.002 mol of acetyl acetone as a stabilizer, and then the resultant mixture was stirred at room temperature for 1 hour, to prepare the solution composition for zinc tin oxide semiconductor. The prepared zinc tin oxide semiconductor solution composition was coated on the substrate S by spin coating, like Example 1, and then was subjected to heat treatment at a temperature of 250° C. for 6 hours, thereby forming a zinc tin oxide semiconductor layer. Next, aluminum source and drain electrodes were stacked, thereby manufacturing a zinc tin thin film transistor. Electrical properties of the thin film transistor were summarized in FIG. 14 and Table 1.

### Comparative Example 2

A solution composition for zinc tin oxide semiconductor prepared as Comparative Example 1 of the present invention was coated on the substrate S by spin coating, and then was subjected to heat treatment at a temperature of 350° C. for 1 hour, thereby forming a zinc tin oxide semiconductor layer. Next, aluminum source and drain electrodes were stacked, thereby manufacturing a zinc tin thin film transistor. Electrical properties of the thin film transistor were summarized in FIG. 15 and Table 1.

TABLE 1
Evaluation on electrical properties of fluorine doped metal oxide semiconductor.

| | | Heat | | Charge | | Sub- | | |
|---|---|---|---|---|---|---|---|---|
| Examples and | | treatment | | carrier | On-off | threshold | Threshold | Fluorine |
| Comparative | Final | temperature | | mobility | current | swing | voltage | content |
| Examples | Composition | [° C.] | Precursor | [cm²V⁻¹s⁻¹] | ratio | [V/decade] | [V] | [F/Metal, %] |
| Example1 | ZTO:F | 250 | ZnF₂: | 2.85 | >10⁷ | 0.87 | 6.0 | 12.1 |
| | | | SnF₂ | | | | | |
| Example2 | ZTO:F | 350 | ZnF₂: | 7.93 | >10⁸ | 0.30 | 2.8 | 6.4 |
| | | | SnF₂ | | | | | |
| Example3 | ZTO:F | 350 | Zn(NO₃)₂: | 6.14 | >10⁷ | 0.47 | 8.6 | 1.5 |
| | | | SnF₂ | | | | | |
| Example4 | ZTO:F | 350 | NH₄F: | 9.94 | >10⁶ | 0.61 | 8.1 | 1.4 |
| | | | Zn(NO₃)₂: | | | | | |
| | | | SnF₂ | | | | | |
| Example5 | IZO:F | 250 | ZnF₂: | 5.46 | >10⁷ | 0.26 | 12.12 | 5.5 |
| | | | InF₃ | | | | | |
| Example6 | IZO:F | 350 | ZnF₂: | 21.14 | >10⁸ | 0.25 | 7.1 | 1.7 |
| | | | InF₃ | | | | | |
| Example7 | AIO:F | 350 | Al(NO₃)₃: | 6.47 | >10⁷ | 0.97 | 9.2 | 2.5 |
| | | | InF₃ | | | | | |
| Example8 | GIO:F | 350 | Ga(NO₃)₃: | 6.95 | >10⁷ | 0.89 | 6.3 | 2.4 |
| | | | InF₃ | | | | | |
| Comparative | ZTO | 250 | Zn(Ac)₂: | — | ~10² | — | — | — |
| Example1 | | | SnCl₂ | | | | | |
| Comparative | ZTO | 350 | Zn(Ac)₂: | 0.20 | ~10⁶ | 0.61 | 23.43 | — |
| Example2 | | | SnCl₂ | | | | | |

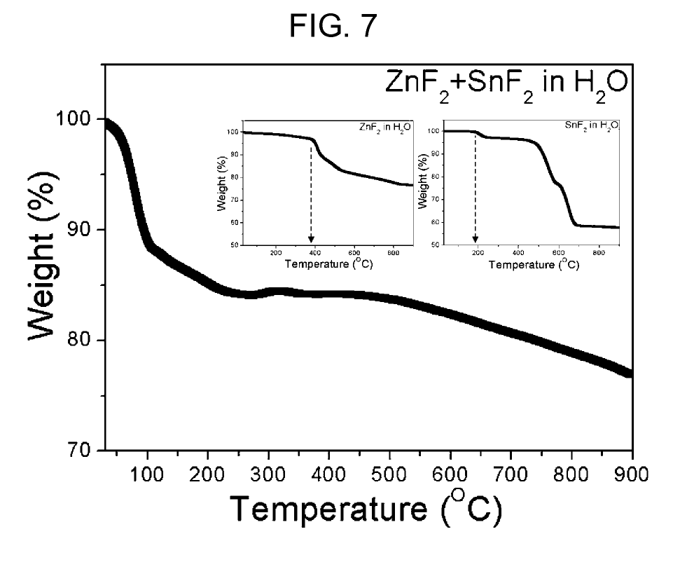

FIG. 7 is a graph showing thermal decomposition property analysis of a powder obtained by coating the aqueous solution composition for fluorine doped metal oxide semiconductor on a slide glass and performing heat treatment on the coated glass at a temperature of 100 to 120° C. for 6 hours to remove moisture. Inserted figures in FIG. 7 are graphs showing thermal decomposition analysis results of TGA samples, which have a fluorine doped zinc oxide component type and a fluorine doped tin oxide component type, respectively. As for the samples having respective component types, rapid thermal decomposition started at temperatures of about 400° C. and about 200° C., respectively. However, in a sample having a fluorine doped zinc tin oxide component type, which is a mixture of the two component types, thermal decomposition started from room temperature. This shows that different kinds of monomers are quickly formed into oligomers by hydrolysis and condensation, even at room temperature.

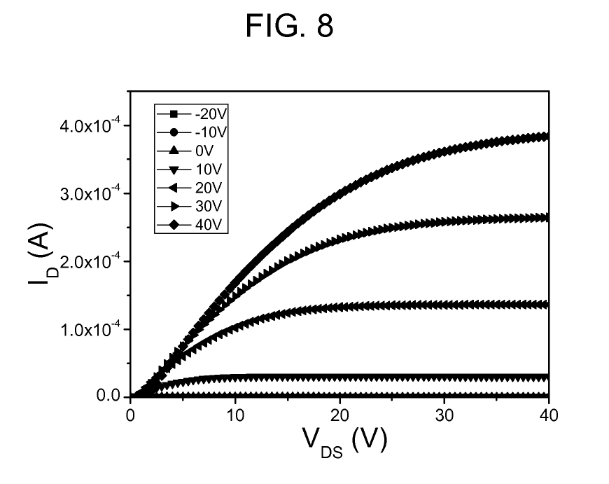

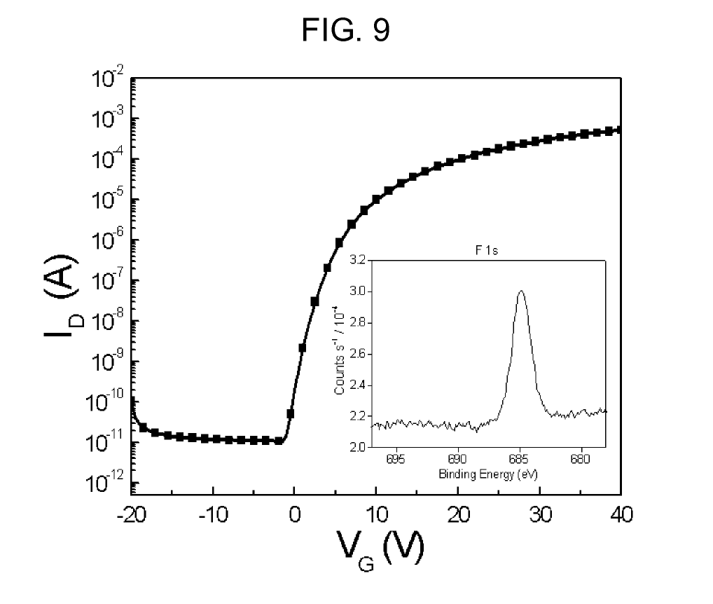

FIGS. 8 and 9 are graphs showing current-voltage characteristics and a transfer curve of the thin film transistor including the fluorine doped zinc tin oxide semiconductor layer according to Example 1 of the present invention. From these, charge carrier mobility, on-off current ratio, threshold voltage, sub-threshold swing, and the like, which exhibit the performance of the fluorine doped metal thin film transistor, were summarized in Table 1. The thin film transistors are well operated at an enhancement mode, presenting excellent semiconductor properties. An inserted figure in FIG. 9 shows F is peak analysis results of X-ray photoemission spectra, which indicates the presence or absence of fluorine and the amount of fluorine in the fluorine doped metal oxide semiconductor layer. The analysis results were summarized in Table 1.

The amount of fluorine contained in the fluorine doped metal oxide semiconductor is determined depending on the amount of fluorine in the precursor used. Example 4, in which a fluorine organic compound was added, is not significantly different from Example 3 in view of the amount of fluorine contained in the manufactured fluorine doped metal oxide semiconductor, but had excellent charge carrier mobility. The reason is guessed that, although a condensation reaction between monomers is slow due to the presence of a nitrate ion in the synthesis solvent, ammonium fluoride is added to create a reaction with the nitrate ion, thereby generating ammonium nitrate while promoting the condensation reaction between monomers, and thus, the ammonium fluoride added functions as a precursor as well as a catalyst in the synthesis solvent. Therefore, in a case where a fluorine organic compound is applied, excellent charge carrier mobility can be obtained.

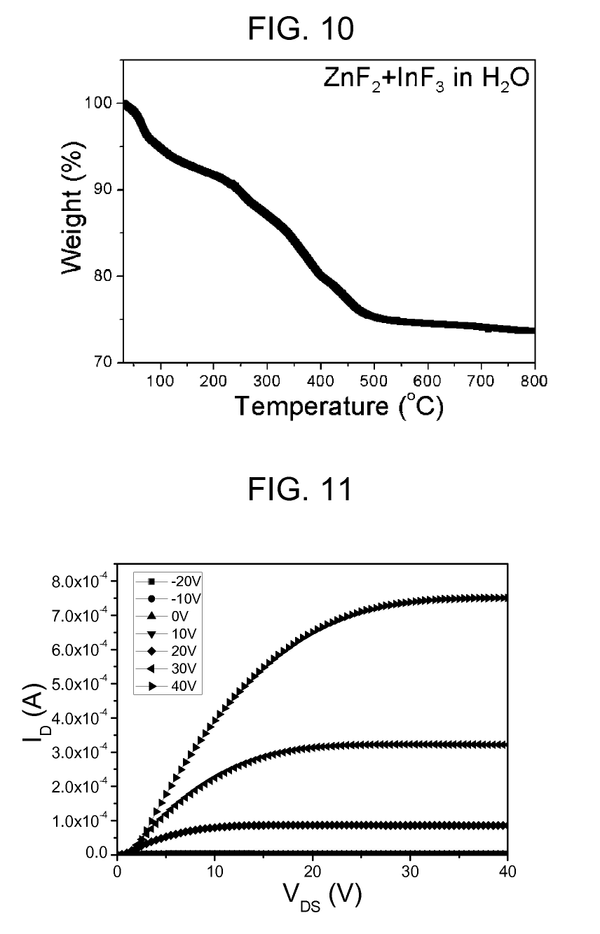

FIG. 10 shows thermal decomposition property of a composition for fluorine doped indium zinc oxide semiconductor of Example 6. The thermal decomposition property at room temperature by condensation of a metal hydroxide monomer and a hydroxyl-fluoride monomer, which are different kinds of monomers, like in FIG. 7, was observed.

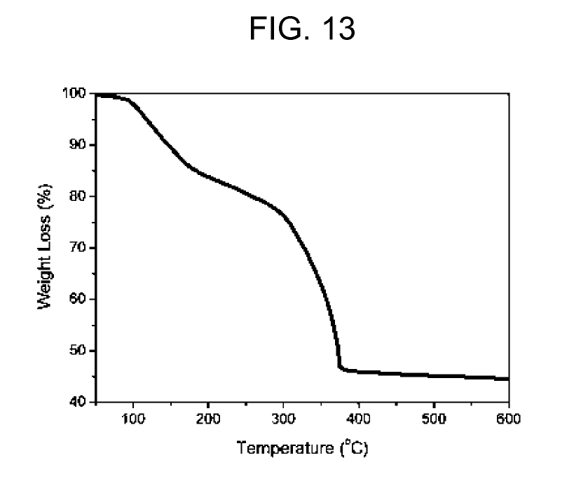

FIG. 13 shows a thermogravimetric analysis result of Comparative Example 1. As the result of thermogravimetric analysis, thermal decomposition of zinc acetate into zinc oxide at a temperature of 200 to 300° C. was observed, and thermal decomposition of tin chloride into tin oxide at a temperature of 300 to 400° C. was observed. The degree of thermal decomposition is no less than 55% higher than the aqueous solution composition for fluorine doped zinc tin oxide semiconductor. This means that the amount of organic materials to be decomposed by heat treatment is more in Comparative Example 1 than in the aqueous solution composition for fluorine doped zinc tin oxide semiconductor.

The fluorine doped metal oxide semiconductor, by way of illustration, is applied to the thin film transistor in the above embodiments, but can be applied to any element that requires a semiconductor thin film without limitation to this. In addition, the present invention, by way of illustration, is applied to only the bottom gate structure thin film transistor in the above embodiments, but can be applied to a thin film transistor having any structure including a top gate structure thin film transistor without limitation to this.

According to the present invention, the aqueous solution composition for fluorine meal oxide semiconductor has a solution form, which leads to simplify the manufacturing process and lower the manufacturing cost, and exhibits excellent semiconductor properties, such as charge carrier mobility, current ratio, threshold voltage, sub-threshold swing, and the like, based on higher current ratio as compared with the existing composition. Furthermore, the present invention leaves less organic residues than a solution composition using an organic solvent, thereby significantly lowering a temperature for heat treatment of manufacturing the fluorine doped metal oxide semiconductor. In addition, a thin film transistor including the semiconductor manufactured according to the present invention has excellent performance, considering the manufacturing temperature.

What is claimed is:

1. An aqueous solution composition for fluorine doped metal oxide semiconductor, comprising:
a fluorine compound precursor made of one or two or more selected from the group consisting of a metal compound containing fluorine and an organic material containing fluorine; and
an aqueous solution containing water or catalyst.

2. The aqueous solution composition for fluorine doped metal oxide semiconductor of claim 1, wherein the metal compound containing fluorine is one or two or more selected from the group consisting of metal fluoride, metal fluoride hydrate, metal fluoro salt, metal fluoro alkoxide, metal fluoroxo-oligomer, and metal fluoroxo-polymer.

3. The aqueous solution composition for fluorine doped metal oxide semiconductor of claim 1, wherein a metal of the metal compound containing fluorine is one or two or more selected from Li, Na, K, Rb, Sc, Be, Mg, Ca, Sr, Ba, Ti, Zr, Hf, V, Nb, Ta, Cr, Mo, W, Mn, Te, Re, Fe, Ru, Os, Co, Rh, Ir, Ni, Pd, Pt, Cu, Ag, Au, Zn, Cd, Hg, B, Al, Ga, In, Tl, Si, Ge, Sn, Pb, P, As, Sb, and Bi.

4. The aqueous solution composition for fluorine doped metal oxide semiconductor of claim 1, wherein the metal compound containing fluorine is one or two or more selected from the group consisting of AlF₃, AgF, BaF₂, BiF₃, BiF₅, CdF₂, CaF₂, CeF₃, CeF₅, CsF₂, CrF₃, CoF₂, CoF₃, CuF₂, DyF₃, ErF₃, EuF₂, GaF₃, GdF₃, GeF₂, GeF₄, HfF₄, HoF₃, InF₃, FeF₃, LaF₃, PbF₂, PrF₃, LiF, MgF₂, MnF₂, MnF₃, Hg₂F₂, HgF₂, HgF₄, NaF, NbF₄, NdF₃, NiF₂, MoF₆, KF, RbF, SbF₃, SbF₅, ScF₃, SiF₄, SnF₂, SnF₄, SrF₂, TaF₅, TbF₃, TiF₃, TiF₄, TlF, TmF₃, VF₃, WF₅, YF₃, YbF₃, ZnF₂, ZrF₄, AlF₃.zH₂O, AlF₃.3H₂O, CrF₃.4H₂O, CoF₂.4H₂O, CuF₂.zH₂O, FeF₃.3H₂O, FeF₂.4H₂O, InF₃.3H₂O, KF.2H₂O, GaF₃.3H₂O, ZnF₂.zH₂O, ZrF₄.zH₂O, SnF₂(acac)₂, SnF (OC₂H₅)(acac)₂, SnF(OCH(CH₃)₂)(acac)₂, SnF(OC(CH₃)₂C₂H₅)(acac)₂, (CF₃COCHCOCH₃)₂—Sn_{f} C₃₃H₇₀F₂Sn₂, [(CH₃)₂CHCH₂]₂AlF, and [(CH₃CH₂CH₂CH₂)₃SnF]ₙ (Here, z and n each are a natural number of 1 or greater)

5. The aqueous solution composition for fluorine doped metal oxide semiconductor of claim 1, wherein the organic material containing fluorine is selected from the group consisting of HF, NH₄F, NH₄F.HF, NH₄HF₂, C₆H₅F, C₂H₂F₂, C₃F₃N₃, CF₃COOH, CF₃CF₂CF₂CO₂H, CF₃CH₂OH, CHF₂CHF₂, CHF₂CF₃, CHF₂CH₃, CF₃CH₂CF, CH₃CF₃, CBr₂F₂, CHF₂CH₂F, CF₃CH₂CF₃, CF₃CFCF₂, CF₃CH₂F, (CH₃)₄NF, CH₃ (CH₂)₆F, CH₃ (CH₂)₇F, CH₃ (CH₂)₄F, (CH₃)₃SiF, (O₂N)₂C₆H₃F, CF₃C₆H₄NH₂, C₆H₄FNO, (C₂H₅)₃N.3HF, C₈H₉FN₂O₂S.HCl, C₇H₈FNO₃S, CH₃COF, C₆H₅SO₂F, C₆H₅COF, C₅H₅N.(HF)ₓ, CH₃C₆H₄SO₂F, CF₃(CF₂)₃SO₂F, CF₃(CF₂)₇SO₂F, C₇H₇FO₂S, C₆H₅CH₂N(CH₃)₃F.zH₂O, (here, x and z independently represent a natural number of 1 or greater) [CH₃(CH₂)₃]₄NF, [CH₃ (CH₂)₃]₄NF.zH₂O, [CH₃ (CH₂)₃]₄NF.3H₂O, (CH₃)₄N (F).4H₂O, (C₂H₅)₄N (F).2H₂O, (C₂H₅)₄NF.zH₂O, H₂C₆H₃(Cl) SO₂F, ICF₂CF₂OCF₂CF₂SO₂F, and [2,4,6-(CH₃)₃C₆H₂]₂BF.

6. The aqueous solution composition for fluorine doped metal oxide semiconductor of claim 1, wherein the aqueous solution composition for fluorine doped metal oxide semiconductor further comprises a metal salt.

7. The aqueous solution composition for fluorine doped metal oxide semiconductor of claim 6, wherein an anion of the metal salt is one or more selected from the group consisting of hydroxide, nitrate, acetate, propionate, acetylacetonate, 2,2,6,6-tetramethyl-3,5-heptandionate, methoxide, secondary-butoxide, tertiary butoxide, n-propoxide, i-propoxide, ethoxide, phosphate, alkyl phosphate, perchlorate, sulfate, iodide, alkyl sulfonate, phenoxide, bromide, and chloride.

8. The aqueous solution composition for fluorine doped metal oxide semiconductor of claim 1, wherein the fluorine compound precursor is involved in formation of a complex, or a hydrolysis or condensation reaction within the aqueous solution including the water or the catalyst.

9. The aqueous solution composition for fluorine doped metal oxide semiconductor of claim 8, wherein the hydrolysis or condensation reaction induces fluorine doped metal oxide monomers or oligomers by a reaction between the fluorine compound precursor and the aqueous solution including water or catalyst.

10. The aqueous solution composition for fluorine doped metal oxide semiconductor of claim 8, wherein the complex is formed by coordinating one or two or more ligands selected from water, a hydroxyl group, an amine group, a carbonyl group, a halogen group, and a cyano group, to a metal ion.

11. The aqueous solution composition for fluorine doped metal oxide semiconductor of claim 1, wherein the aqueous solution including catalyst is one or more selected from the group consisting of an aqueous hydrochloride solution, an aqueous sulfuric acid solution, an aqueous nitric acid solution, an aqueous fluoric acid solution, an aqueous boric acid solution, an aqueous phosphoric acid solution, an aqueous carbonic acid solution, an aqueous peroxide solution, an aqueous acetic acid solution, ammonia water, and an aqueous urea solution.

12. A method for manufacturing a fluorine doped metal oxide semiconductor, comprising:
a) coating a substrate with the aqueous solution composition for fluorine doped metal oxide semiconductor of claims 1; and
b) performing heat treatment on the coated substrate to form the fluorine doped metal oxide semiconductor.

13. A fluorine doped metal oxide semiconductor manufactured by claim 12.

14. A thin film transistor, comprising:
a gate substrate;
the fluorine doped metal oxide semiconductor of claim 13, overlapping the gate substrate;
a source electrode electrically connected to the fluorine doped metal oxide semiconductor; and
a drain electrode electrically connected to the fluorine doped metal oxide semiconductor and facing the source electrode.
